(19) United States
(12) Patent Application Publication
(10) Pub. No.: US 2006/0166459 A1
(43) Pub. Date: Jul. 27, 2006

(54) Semiconductor apparatus and method of producing the same

(75) Inventors: Takuo Ohashi, Tokyo (JP); Takeshi Suwa, Tokyo (JP); Susumu Sakurai, Tokyo (JP); Taishi Kubota, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/338,728

(22) Filed: Jan. 25, 2006

(30) Foreign Application Priority Data
Jan. 26, 2005 (JP) 2005-017742

(51) Int. Cl. H01L 21/76; H01L 29/00

(52) U.S. Cl. 438/425; 257/510

(57) ABSTRACT

In a method of producing a semiconductor apparatus, which method includes a trench forming step of forming a trench in a silicon substrate and an inner wall oxidizing step of forming an oxide film on an inner wall of the trench;
the inner wall oxidizing step being performed by wet oxidization with a low concentration of moisture mixed in oxygen to form the oxide film so that a stress caused between the oxide film and the silicon substrate is not greater than 3.5×10⁹ (dyne/cm²) and a radius at a corner of the trench is 8 nm or more.

This application claims priority to prior Japanese patent application JP 2004-17742, the disclosure of which is incorporated herein by reference.

### BACKGROUND OF THE INVENTION

This invention relates to a semiconductor apparatus and, in particular, to a semiconductor apparatus produced by shallow trench isolation and a method of producing the same.

In recent years, a semiconductor device is more and more reduced in size and a semiconductor apparatus becomes higher in degree of integration and larger in scale. As device isolation for the semiconductor apparatus, shallow trench isolation (hereinafter abbreviated to STI) is used. In the STI, an insulating film is buried in a trench to isolate adjacent device regions from each other. As compared with LOCOS (Local Oxidation of Silicon), no bird's beak is generated in the STI. Thus, the STI is suitable for a higher degree of integration.

However, the STI is disadvantageous in the following respects. In case where the STI is used as the device isolation, an oxide film as the insulating film is deposited on an inner wall of the trench. Depending upon an oxidization method used in forming the oxide film, a stress in the trench is varied to affect formation of a very small crystal defect. As a consequence, a junction leakage current is increased. Further, in case where the STI is used as the device isolation, an angled portion is formed at an upper part of an STI region. A gate oxide film at that portion is locally reduced in thickness to cause concentration of an electric field. This results in degradation in reliability of the gate oxide film and deterioration in performance of a transistor. In view of the above, as an oxidization condition for oxidizing the inner wall of the trench, it is desired to reduce the stress and to round an upper corner of the STI region. However, an existing method of oxidizing the inner wall of the trench using mere wet oxidization is insufficient and an improvement is desired.

In order to solve the above-mentioned problems, several proposals have been made. For example, Japanese Unexamined Patent Application Publication (JP-A) No. 2002-43407 (corresponding to US 2002020867 A1) discloses that, in order to round the upper corner of the STI region, it is optimum as an oxidization condition that a ratio of a moisture content to a total gas content used for oxidization is 20 to 40%. If the above-mentioned ratio is less than 20%, roundness of the corner is insufficient. If the above-mentioned ratio is more than 40%, it is difficult to control a film thickness. Japanese Unexamined Patent Application Publication (JP-A) 2001-44273 discloses a method comprising the steps of carrying out isotropic etching to form a shallow groove with rounded corners, carrying out anisotropic etching to form a trench, and carrying out wet oxidization to oxidize an inner wall of the trench. However, the former publication teaches an oxidization technique for rounding the corner and the latter publication teaches a trench etching technique using the isotropic etching. Therefore, those techniques are not applicable to a miniaturized semiconductor apparatus. Under the circumstances, it is desired to establish an oxidization method which is applicable to a miniaturized semiconductor device and which is capable of reducing a stress and of rounding an upper corner of an STI region.

As described above, it is desired to establish, as inner wall oxidization in the STI, an oxidization method capable of reducing a stress and of rounding an upper corner of an STI region. By reducing the stress, it is possible to suppress formation of a very small crystal defect and to reduce a junction leakage current. Further, by rounding the upper corner of the STI region, it is possible to suppress variation in thickness of a gate oxide film at a corner portion so as to prevent electric field concentration. As a consequence, a reliability of the gate oxide film is improved so that a transistor and a semiconductor apparatus high in reliability are obtained.

### SUMMARY OF THE INVENTION

It is an object of this invention to provide a highly-reliable semiconductor apparatus by establishing, as inner wall oxidization in STI, an optimum oxidization method which is for forming an inner wall oxide film and which is capable of reducing a stress and of rounding an upper corner of an STI region and to provide a method of producing the same.

Methods according to this invention and a semiconductor apparatus according to this invention are as follows:

(1) A method of producing a semiconductor apparatus, comprising:

a trench forming step of forming a trench in a silicon substrate; and

an inner wall oxidizing step of forming an oxide film on an inner wall of the trench;

the inner wall oxidizing step being performed by wet oxidization with a low concentration of moisture mixed in oxygen to form the oxide film so that a stress caused between the oxide film and the silicon substrate is not greater than 3.5×10⁹ (dyne/cm²) and a radius at a corner of the trench is 8 nm or more.

(2) A method as described in (1), wherein the concentration of moisture is not greater than 10% and is not smaller than 0.01% at an oxidization temperature of 1100° C.

(3) A method as described in (1), wherein the concentration of moisture is not greater than 2% and is not smaller than 0.01% at an oxidization temperature of 1000° C.

(4) A method as described in (1), wherein the concentration of moisture is not greater than 1% and is not smaller than 0.01% at an oxidization temperature of 950° C.

(5) A method as described in (1), wherein the concentration of moisture has an upper limit given by a curve containing a point of 10% at an oxidization temperature of 1100° C. and a lower limit of 0.01%.

(6) A semiconductor apparatus comprising a silicon substrate provided with a trench having a rounded corner with a radius of 8 nm or more and an oxide film formed on an inner wall of the trench and deposited by wet oxidization at a moisture concentration between an upper limit represented given by a curve containing a point of 10% at an oxidization temperature of 1100° C. and a lower limit of 0.01%.

In this invention, the inner wall oxide film in the STI is deposited under the oxidization condition such that the moisture concentration is not greater than that given by the curve containing the point where the moisture concentration is 10% at the oxidization temperature of 1100° C. and is not smaller than 0.01%. Thus, a stress in the trench in the STI is reduced so that generation of a leakage current is prevented. Further, the corner of the trench is rounded to achieve a uniform thickness of a gate oxide film at a corner portion. By depositing the inner wall oxide film in the STI using the above-mentioned oxidization method, a highly-reliable semiconductor apparatus and a method of producing the same are obtained.

### BRIEF DESCRIPTION OF THE DRAWINGS

FIGS. 1A to 1E are sectional views for describing a process of producing a semiconductor apparatus according to this invention;

FIG. 2 is a graph showing correlation between a moisture concentration and a stress in this invention;

FIG. 3 is a graph showing correlation between the stress and a dislocation density;

FIG. 4 is a graph showing correlation between the dislocation density and a junction leakage current;

FIG. 5 is a graph showing an optimum range of an oxidization condition, given by an oxidization temperature and the moisture concentration, with respect to the leakage current;

FIG. 6 is a graph showing correlation between the moisture concentration and an STI shoulder radius in this invention;

FIG. 7 is a graph showing correlation between a dry oxidization temperature and the STI shoulder radius;

FIG. 8 is a graph showing correlation between the oxidization temperature and the STI shoulder radius; and

FIG. 9 is a view showing an optimum range of an oxidization condition, given by the oxidization temperature and the moisture concentration, with respect to the STI shoulder radius.

### DESCRIPTION OF THE PREFERRED EMBODIMENT

This invention relates to wet oxidization using a low moisture concentration so as to form an inner wall oxide film in STI with a less stress and a rounded upper corner of an STI region.

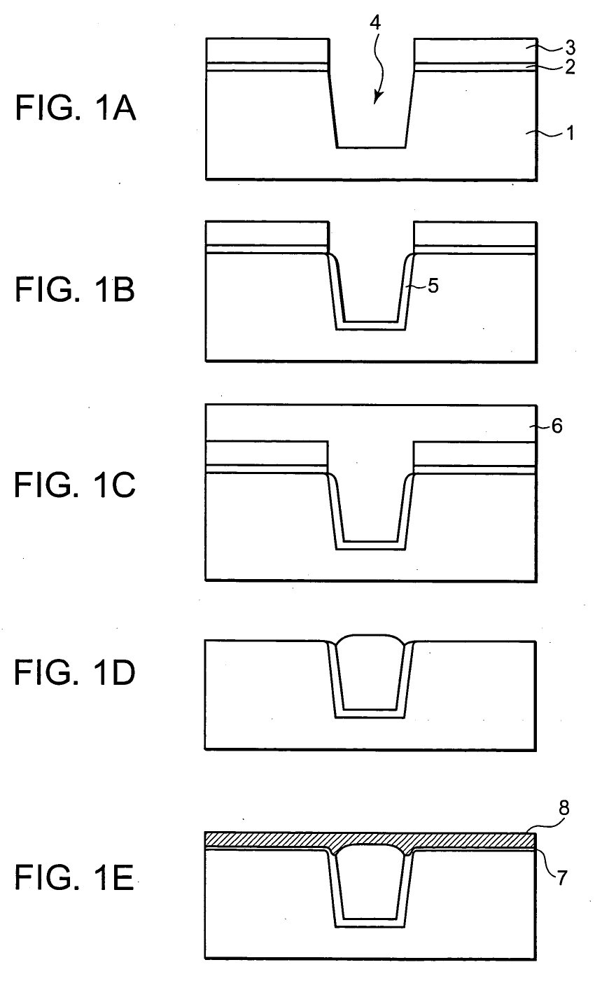

Referring to FIGS. 1A to 9, an embodiment of this invention will be described.

At first referring to FIGS. 1A to 1E, a process of producing a semiconductor apparatus according to this invention will be described. In the following description, typical film thicknesses are mentioned. However, these film thicknesses are merely for the purpose of explanation and this invention is not limited to the embodiment and the film thicknesses described hereinafter.

Referring to FIG. 1A, a pad oxide film 2 having a thickness of 10 nm and a nitride film 3 having a thickness of 120 nm are deposited on a silicon substrate 1. By lithography and etching, a trench 4 is formed inside the silicon substrate 1. The trench 4 has an angle nearly equal to 90 degrees at a corner portion as an upper edge of the silicon substrate 1, which forms a boundary with the pad oxide film 2. Referring to FIG. 1B, an inner wall oxide film 5 having a thickness of 10 to 20 nm is deposited on an inner wall of the trench 4. Since the inner wall oxide film 5 is formed along the inner wall of the trench 4, there arise problems of occurrence of a stress owing to a difference in coefficient of thermal expansion between the silicon substrate 1 and the oxide film 5 and nonuniformity in thickness of a gate oxide film to be deposited at an upper corner of the trench 4 in a later step. The present inventors studied an oxidization condition upon forming the inner wall oxide film 4 to find an optimum condition.

Referring to FIG. 1C, a trench oxide film 6, such as a HDP (High Density Plasma) film or a TEOS (Tetra Ethyl Ortho Silicate) film, having a thickness of 400 nm is buried in the trench 4. Referring to FIG. 1D, the trench oxide film 6 is planarized by CMP (Chemical Mechanical Polishing) to an upper surface of the patterned nitride film 3 and then the nitride film 3 and the pad oxide film 2 remaining on the silicon substrate 1 are removed. By the above-mentioned steps, a device isolation process by the STI is completed. Thereafter, each semiconductor device is formed in an active region. For example, as illustrated in FIG. 1E, a gate oxide film 7 is grown and a gate polysilicon film 8 to serve as a gate electrode is formed. If the trench 4 has an angled corner, the thickness of the gate oxide film 7 at a corner portion is reduced so that the reliability of a transistor is degraded. This invention aims to optimize the oxidization condition upon forming the inner wall oxide film shown in FIG. 1B.

For optimization as to the inner wall oxide film, a first point is to reduce a stress and a second point is to round an upper corner of the trench. In this embodiment, oxidization is performed using dry oxidization and wet oxidization. By changing an oxidization temperature and a moisture concentration, the stress produced between the silicon substrate and the inner wall oxide film and the roundness of the upper corner have been examined. An oxidization apparatus may be of a batch-processing furnace type or of a single-wafer RTP (Rapid Thermal Processing) type.

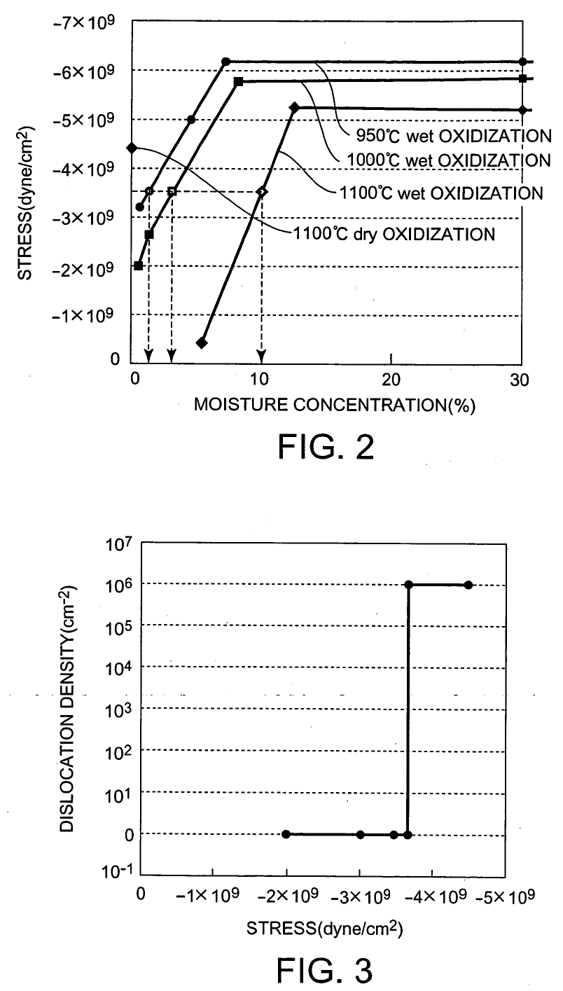

FIG. 2 shows a correlation between the moisture concentration and the stress. The moisture concentration is a value calculated by H₂O/(H₂O+O₂). The dry oxidization is an oxidization technique using O₂ alone without moisture and incorporation of the moisture is controlled on the order of PPM. Thus, a dry oxidization condition corresponds to the moisture concentration of 0%. In FIG. 2, the stress is smaller as the oxidization temperature is higher. Further, the stress is smaller as the moisture concentration is lower. However, under the dry oxidization condition corresponding to the moisture concentration of 0%, the stress is increased on the contrary as shown in the figure. Generally, an excessive moisture concentration increases the stress while a low moisture concentration reduces the stress. However, in the dry oxidization without supplying any moisture at all, the stress is increased to the contrary. Accordingly, it is important to supply the moisture and to control the moisture concentration to a low level.

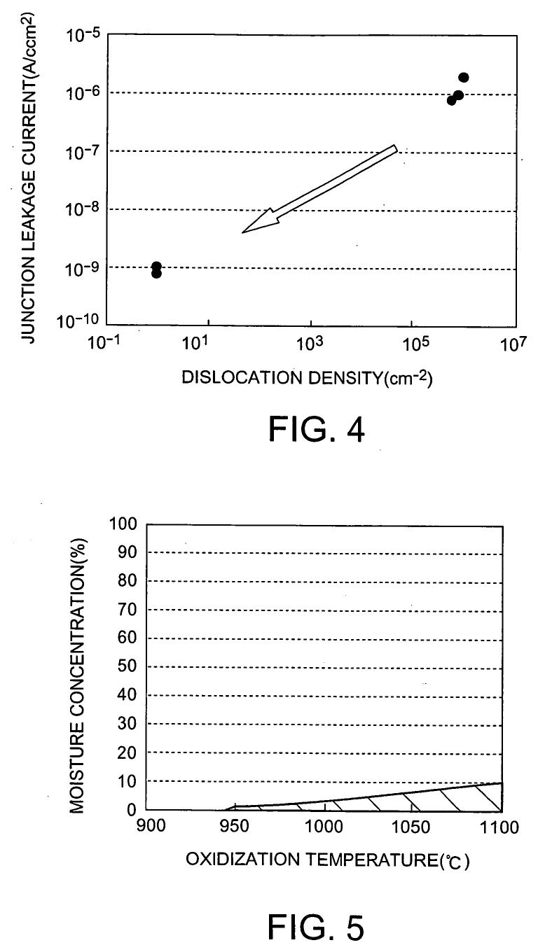

FIG. 3 shows a correlation between the stress and a dislocation density. As illustrated in FIG. 3, when the stress is greater than 3.5×10⁹ (dyne/cm²), the dislocation density is abruptly increased. FIG. 4 shows a correlation between the dislocation density and a junction leakage current. As illustrated in FIG. 4, if the dislocation density is increased, the junction leakage current is increased. When the stress is great, distortion or strain is caused in the silicon substrate and a crystal defect is formed. Due to the crystal defect, the leakage current is increased. Accordingly, the stress caused upon formation of the oxide film must be decreased.

From the above, the oxidization condition such that the stress is smaller than 3.5×10⁹ (dyne/cm²) is required in order to avoid occurrence of dislocation. By suppressing the stress to a level smaller than 3.5×10⁹ (dyne/cm²) and decreasing a very small crystal defect on a side surface of the trench in the STI, the junction leakage current can be reduced. By reducing the stress in the above-mentioned manner, it is possible to suppress concentration of metal contamination in a stress field and to effectively reduce the junction leakage current.

A suitable moisture concentration depends upon the oxidization temperature. As the oxidization temperature is lower, a lower moisture concentration is preferable. FIG. 5 shows an optimum range of the oxidization condition given by the oxidization temperature and the moisture concentration. The range illustrated in FIG. 5 represents a correlation between the oxidization temperature and the moisture concentration. As a typical relationship between the oxidization temperature and the moisture concentration, the moisture concentration is 1% or less at 950° C., 2% or less at 1000° C., and 10% or less at 1100° C. At other temperatures around these temperatures, a corresponding moisture concentration is read from a data curve illustrated in the figure.

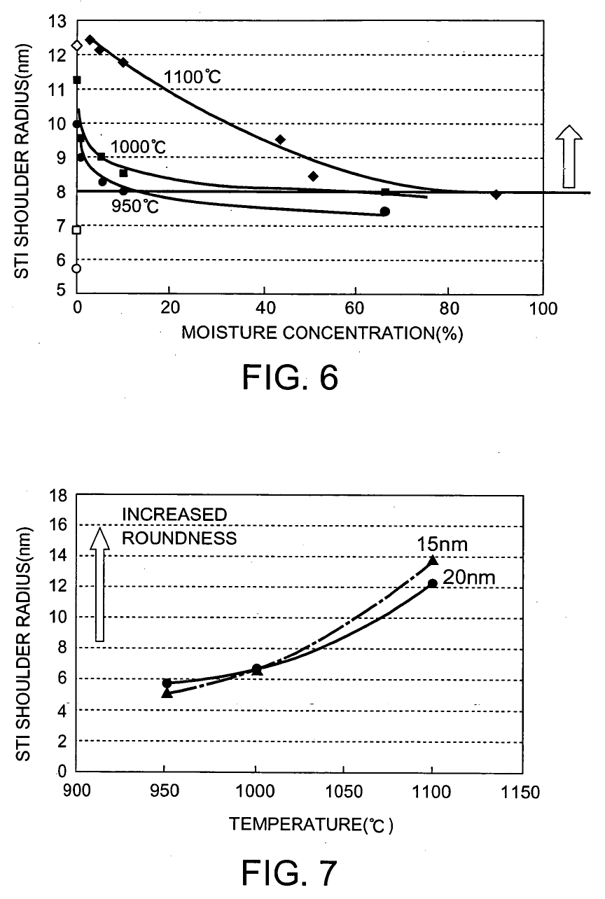

Next referring to FIGS. 6 to 9, description will be made of roundness at the upper corner of the trench. Herein, as an index of the roundness, a radius of an inscribed circle at an STI shoulder portion is used and is called an STI shoulder. As the radius is greater, the roundness at the corner is increased. At present, a generally uniform gate oxide film is formed when the radius is greater than 7.5 nm. Therefore, in order to form a more uniform oxide film, the condition such that the radius is not smaller than 8 nm is selected. FIG. 6 shows the moisture concentration and the STI shoulder radius with respect to the oxidization temperature as a parameter. In FIG. 6, the radius not smaller than 8 nm is obtained at the moisture concentration of 10% or less at 950° C., 66% or less at 1000° C., and 90% or less at 1100° C.

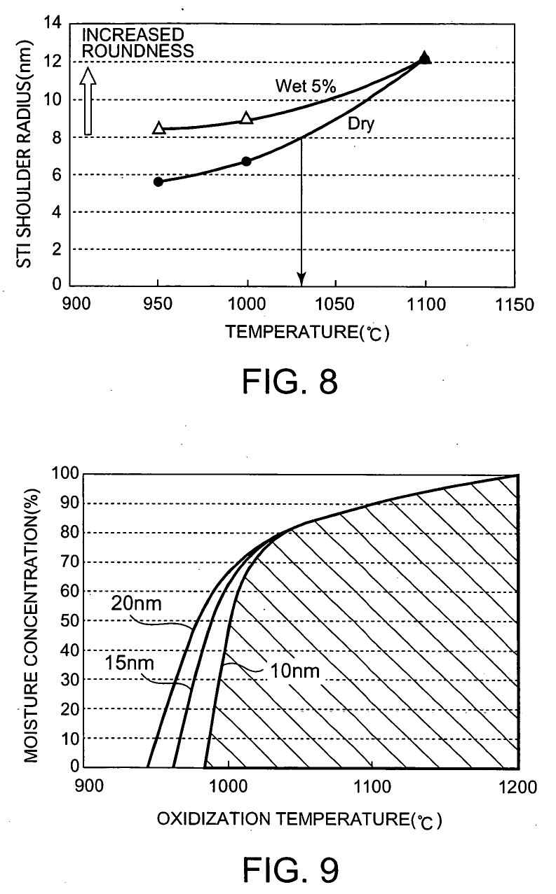

As seen from FIGS. 7 and 8, in case of the dry oxidization, the oxidization temperature must be as high as 1030° C. or more in order to obtain the radius of 8 nm or more. The dry oxidization at the oxidization temperature lower than 1030° C. is insufficient. Depending upon the thickness of the inner wall oxide film, a suitable condition is different. At the temperature lower than 1000° C., a lower moisture concentration is required as the thickness is smaller. FIG. 9 shows an optimum range of the oxidization condition such that the radius of the STI shoulder portion is 8 nm or more. As seen from FIG. 9, the moisture concentration of 60% or less is required at 1000° C. if the film thickness is 15 nm. The moisture concentration of 40% or less is required at 1000° C. if the film thickness is 10 nm.

In order to round the corner in the method of oxidizing the inner wall of the trench, two points are important. First, the moisture concentration in the wet oxidization is lowered. Second, the oxidization temperature is elevated. As the moisture concentration is lower, the radius is increased and the corner is rounded. However, like in case of the stress, the roundness is decreased in the dry oxidization corresponding to the moisture concentration of 0%. Thus, the moisture concentration is required even if it is very small.

As the oxidization temperature is higher, the corner is rounded even at a higher moisture concentration. By inner wall oxidization within a range satisfying the above-mentioned condition, the STI corner portion is rounded. Thus, since the corner portion is rounded, it is possible to prevent the gate oxide film from being locally reduced in thickness and to prevent concentration of the electric field. As a result, the reliability of the gate oxide film is improved and kink characteristics of the transistor can be suppressed. Thus, a performance improving effect is achieved.

Consideration will collectively be made of the range of the oxidization condition for rounding the corner (FIG. 9) and the range of the oxidization condition for reducing the stress (FIG. 5). The oxidization condition satisfying both FIG. 5 and FIG. 9 is the range shown in FIG. 5 in which the moisture concentration is lower than that given by the curve containing the points of the moisture concentration of 1% at the oxidization temperature of 950° C., 2% at 1000° C., and 10% at 1100° C. For simplicity of description, the range shown by the curve in FIG. 5 is represented by the range represented by the curve containing the point of the temperature of 1100° C. at the moisture concentration of 10%. The lower limit of the moisture concentration is preferably 0.01% so as to facilitate control of a flow controller as a production facility.

By carrying out inner wall oxidization under the above-mentioned condition, the stress around the STI is reduced and the corner of the STI shoulder portion can be rounded. These phenomena will be considered. In case of the wet oxidization, oxidization is performed in an atmosphere of O₂+H₂O. At this time, two reactions occur as follows:
Si+O₂-->SiO₂ (1)
Si+2H₂O-->SiO₂₊₂H₂ (2)
If the moisture concentration is low, the reaction in the formula (2) hardly occurs and the reaction is suspended in an intermediate state of OH—. In this state, strong oxidization is caused so that SiO₂ bond is more tight. As a result, a difference in coefficient of expansion between silicon (Si) and the oxide film (SiO₂) is reduced so that the stress is reduced. If the moisture concentration is lower than a specific ratio at each oxidization temperature, the stress is drastically reduced by the effect of OH—. In case of the dry oxidization, no OH— is present so that the above-mentioned effect can not be obtained. Accordingly, it is necessary to supply even a little moisture and to keep the OH— state.

In this embodiment, the inner wall oxide film in the STI is deposited under the oxidization condition in which the moisture concentration is lower than that given by the curve containing the point of the moisture concentration of 10% at the oxidization temperature of 1100° C. Thus, the stress in the STI is reduced so that occurrence of the leakage current is prevented. Further, the corner of the STI is rounded to achieve uniform thickness of the gate oxide film at the corner portion. By depositing the inner wall oxide film of the STI using the above-mentioned oxidization method, a highly-reliable semiconductor apparatus and a method of producing the same are obtained.

Although this invention has been described in detail in conjunction with the preferred embodiment thereof, this invention is not limited to the foregoing embodiment but may be modified in various other manners within the scope of this invention.

What is claimed is:

1. A method of producing a semiconductor apparatus, comprising:
a trench forming step of forming a trench in a silicon substrate; and
an inner wall oxidizing step of forming an oxide film on an inner wall of said trench;
said inner wall oxidizing step being performed by wet oxidization with a low concentration of moisture mixed in oxygen to form said oxide film so that a stress caused between said oxide film and said silicon substrate is not greater than 3.5×10⁹ (dyne/cm²) and a radius at a corner of said trench is 8 nm or more.

2. A method as claimed in claim 1, wherein the concentration of moisture is not greater than 10% and is not smaller than 0.01% at an oxidization temperature of 1100° C.

3. A method as claimed in claim 1, wherein the concentration of moisture is not greater than 2% and is not smaller than 0.01% at an oxidization temperature of 1000° C.

4. A method as claimed in claim 1, wherein the concentration of moisture is not greater than 1% and is not smaller than 0.01% at an oxidization temperature of 950° C.

5. A method as claimed in claim 1, wherein the concentration of moisture has an upper limit given by a curve containing a point of 10% at an oxidization temperature of 1100° C. and a lower limit of 0.01%.

6. A semiconductor apparatus comprising a silicon substrate provided with a trench having a rounded corner with a radius of 8 nm or more and an oxide film formed on an inner wall of said trench and deposited by wet oxidization at a moisture concentration between an upper limit represented given by a curve containing a point of 10% at an oxidization temperature of 1100° C. and a lower limit of 0.01%.
